(19) United States
(12) Patent Application Publication
(10) Pub. No.: US 2024/0401194 A1
(43) Pub. Date: Dec. 5, 2024

(54) METHOD SYSTEM AND APPARATUS FOR REMOTE SOLID REFILL

(71) Applicant: ASM IP Holding B.V., Almere (NL)

(72) Inventors: Shuaidi Zhang, Chandler, AZ (US); Mustafa Muhammad, Chandler, AZ (US); Moataz Bellah Mousa, Chandler, AZ (US); Paul Ma, Scottsdale, AZ (US); Jonathan Bakke, Phoenix, AZ (US); Todd Robert Dunn, Cave Creek, AZ (US); Eric James Shero, Phoenix, AZ (US); Jereld Lee Winkler, Gilbert, AZ (US); YoungChol Byun, Tempe, AZ (US); Shubham Garg, Gilbert, AZ (US); Jacqueline Wrench, Mesa, AZ (US)

(21) Appl. No.: 18/676,023

(22) Filed: May 28, 2024

Related U.S. Application Data
(60) Provisional application No. 63/470,051, filed on May 31, 2023.

(51) Int. Cl. C23C 16/448; C23C 16/455; C23C 16/52; H01L 21/67

(52) U.S. Cl. CPC C23C 16/4485; C23C 16/45544; C23C 16/45582; C23C 16/52; H01L 21/67017

(57) ABSTRACT

The current disclosure relates to example method, system and apparatus for coupling a delivery vessel disposed at a first location on a substrate processing platform to a remote refill vessel disposed in a second location remote from the substrate processing platform via a first chemical delivery line, storing a chemical in the remote refill vessel in a first phase, changing the chemical in the remote refill vessel to a second phase, transporting the chemical in the second phase, to the delivery vessel via the first chemical delivery line, heating the first chemical delivery line to a first temperature equal to or above a phase change temperature of the chemical, and coupling the delivery vessel to an accumulator via a second chemical delivery line.

### CROSS-REFERENCE TO RELATED APPLICATIONS

This application is a nonprovisional of, and claims priority to and the benefit of, U.S. Provisional Patent Application No. 63/470,051, filed May 31, 2023 and entitled “METHOD SYSTEM AND APPARATUS FOR REMOTE SOLID REFILL,” which is hereby incorporated by reference herein.

### FIELD OF THE DISCLOSURE

The present disclosure relates generally to semiconductor processing equipment and specifically to method, system and apparatus for refilling a chemical precursor delivery vessel.

### BACKGROUND OF THE DISCLOSURE

Semiconductor manufacturing processes such as chemical vapor deposition (CVD) and atomic layer deposition (ALD) involve deposition of thin film on a semiconductor wafer (also referred to herein as a “substrate”). During processing, the wafer is exposed to one or more precursors in a reaction chamber to deposit the thin layers of material. The precursor source is typically stored in delivery vessels onboard a processing tool and delivered to the reaction chamber from the delivery vessels. In order to reduce the need to service and change out delivery vessels delivery vessels are being made progressively larger. However, even large delivery vessels eventually empty and need to be swapped out requiring down-time and possibly quality or safety excursions. Such systems have generally been accepted for their intended purpose. However, there remains a need for improved methods, systems and apparatus for reducing the need to service and change out delivery vessels. The present disclosure provides a solution to this need.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

The current disclosure relates to example methods comprising coupling a delivery vessel disposed at a first location on a substrate processing platform to a remote refill vessel disposed in a second location remote from the substrate processing platform via a first chemical delivery line, storing a chemical in the remote refill vessel in a first phase, changing the chemical in the remote refill vessel to a second phase, transporting the chemical in the second phase, to the delivery vessel via the first chemical delivery line, heating the first chemical delivery line to a first temperature equal to or above a phase change temperature of the chemical, and coupling the delivery vessel to an accumulator via a second chemical delivery line. In various examples, the first phase may be solid and the second phase may be liquid. Changing the phase of the chemical may further comprise melting the chemical by applying heat to the chemical or applying pressure to the chemical, or a combination thereof. In an example, the first phase may be solid and the second phase may be gas. Changing the phase of the chemical may further comprise sublimating the chemical by applying heat to the chemical or reducing a pressure applied to the chemical, or a combination thereof. The remote refill vessel may be disposed in a sub-fab.

In various examples, transporting the chemical in the second phase may further comprise coupling the remote refill vessel and the delivery vessel via a third chemical delivery line to provide a closed-loop circuit with the first chemical delivery line between the delivery vessel and the remote refill vessel, providing a supply of an inert gas via an inert gas supply vessel coupled to the third chemical delivery line via a gas valve to prime the closed-loop circuit with the inert gas, and closing the gas valve subsequent to the priming.

In accordance with various examples of the disclosure, the method may include maintaining pressure in the remote refill vessel between a compressor pump coupled to the third chemical delivery line and a restrictor coupled to the first chemical delivery line, upstream of the delivery vessel. The method may include pumping, with the compressor pump, the inert gas toward the remote refill vessel to carry the chemical in the second phase to the delivery vessel.

The method may include expanding the inert gas and chemical in the second phase into an inner volume of the delivery vessel and solidifying the chemical in the delivery vessel responsive to a resulting pressure drop within the delivery vessel. In an additional aspect, the method may include sublimating the chemical within the delivery vessel, transporting the sublimated chemical from the delivery vessel to the accumulator via the second chemical delivery line, heating the second chemical delivery line to a second temperature sufficient to maintain the chemical in a gaseous state, coupling the accumulator to a reaction chamber, and transporting the chemical from the accumulator to the reaction chamber.

In accordance with various examples of the disclosure, the method may include maintaining a temperature gradient between a first inner volume of the delivery vessel and a second inner volume of the remote refill vessel and returning the chemical to a first phase within the first inner volume. In an example, the method may comprise maintaining the temperature gradient by actively cooling the delivery vessel via a plurality of cooling projections disposed within the first inner volume. The method may include, transporting the chemical in the second phase and pumping the chemical through the first chemical delivery line via a pump coupled to the first chemical delivery line.

The current disclosure further relates to an example substrate processing system, comprising a delivery vessel having a first inner volume, disposed in a first location on a substrate processing platform, a remote refill vessel in fluid communication with the delivery vessel via a first chemical delivery line, the remote refill vessel comprising a second inner volume greater than the first inner volume and disposed in a second location remote from the substrate processing platform, an accumulator coupled between the delivery vessel and a reaction chamber via a second chemical delivery line, and a first heating device proximate the remote refill vessel, operable to heat a chemical disposed in the remote refill vessel sufficient to change the chemical from a first phase to a second phase.

The example substrate processing system may include the first chemical delivery line being coupled to a second heating device operable to maintain the first chemical delivery line at a transport temperature higher than a phase change temperature of the chemical.

The example substrate processing system may include the first chemical delivery line being coupled to a mechanical pump configured to direct the chemical in the second phase through the first chemical delivery line from the remote refill vessel to the delivery vessel.

The example substrate processing system may include the delivery vessel being coupled to a third heating device, or a cooling device, or a combination thereof, wherein the first chemical delivery line may be coupled to the delivery vessel via an inlet valve.

The example substrate processing system may include the cooling device comprising a plurality of cooling projections disposed at a bottom portion of the delivery vessel wherein a temperature of the cooling projections may be selected to return the chemical to the first phase from the second phase.

In various examples, the substrate processing system may include at least one sensor disposed in or adjacent to the first chemical delivery line, the second chemical delivery line, a pump, the delivery vessel or the remote refill vessel, or a combination thereof, to monitor temperature, pressure or pump cycle time or a combination thereof of the chemical and to generate sensor data based on the monitoring and at least one controller communicatively coupled to the at least one sensor and communicatively coupled to the first heating device, the second heating device, the third heating device, the cooling device or the pump, or a combination thereof, the at least one controller configured to receive the sensor data and adjust the first heating device, the second heating device, the third heating device, the pump or the cooling device, or a combination thereof, based on the sensor data.

In an aspect, wherein the first phase of the chemical may be solid and the second phase of the chemical may be gaseous, the substrate processing system may include a third chemical delivery line coupled between the remote refill vessel and the delivery vessel, a compressor pump coupled to the third chemical delivery line upstream of an inert gas source coupled to the third chemical delivery line, wherein the compressor pump may be operable to at least direct inert gas from the inert gas source to the remote refill vessel and a restrictor coupled to the first chemical delivery line upstream of the delivery vessel to maintain the inert gas and the gaseous chemical at a first pressure, between the compressor pump and the restrictor, that may be higher than a second pressure within the delivery vessel, and wherein the restrictor may be operable to open to expand the inert gas and the gaseous chemical into the delivery vessel to solidify the chemical within the delivery vessel. The substrate processing system may further comprise at least one sensor disposed in or adjacent to the first chemical delivery line, the third chemical delivery line, the compressor pump, the restrictor, the inert gas source, the delivery vessel, or the remote refill vessel, or a combination thereof, to monitor a temperature or a pressure or combination thereof of the chemical and to generate sensor data based on the monitoring, and at least one controller communicatively coupled to the at least one sensor and communicatively coupled to the first heating device, the second heating device, the third heating device, the compressor pump, the restrictor, or one or more valves coupled to any of the delivery vessel, the remote refill vessel or the inert gas source, or a combination thereof, wherein the at least one controller may be configured to receive the sensor data and adjust the first heating device, the second heating device, the third heating device, the compressor pump, the restrictor, or the one or more valves coupled to any of the delivery vessel, the remote refill vessel or the inert gas source, or a combination thereof, based on the sensor data. In an aspect, the first phase may be solid and the second phase may be gas or liquid, or a combination thereof.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram illustrating an example substrate processing system;

FIG. 2 is a schematic diagram illustrating an example refill subassembly of the substrate processing system depicted in FIG. 1;

FIG. 3 is a schematic diagram illustrating an example substrate processing system;

FIG. 4 is a schematic diagram illustrating an example refill subassembly of the substrate processing system depicted in FIG. 3;

FIG. 5 is a schematic diagram illustrating an example substrate processing system;

FIG. 6 is a schematic diagram illustrating an example refill subassembly of the substrate processing system depicted in FIG. 5;

FIG. 7 is a flow chart illustrating an example of a solid source refill process;

FIG. 8 is a flow chart illustrating an example of a solid source refill process depicted in FIGS. 3-4;

FIG. 9 is a flow chart illustrating an example of a solid source refill process depicted in FIGS. 5-6; and

FIG. 10 is a flow chart depicting an example substrate processing process that may proceed subsequent to solid source refill depicted in FIG. 8 and/or FIG. 9.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

A chemical reactant or solid source delivery system can include a delivery vessel and a heater (e.g., a radiant heat lamp, resistive heater, and/or the like). The vessel includes the source precursor (which may also be referred to as “chemical” or “chemical precursor”), and which can be a solid (e.g., in powder form) or liquid. The heater heats up the vessel to facilitate the vaporization and/or sublimation of the reactant in the vessel. The vessel can have an inlet and an outlet for the flow of a carrier gas through the vessel. The carrier gas may be inert, for example, nitrogen, argon, or helium. Generally, the carrier gas conveys reactant vapor (e.g., evaporated or sublimated chemical reactant) along with it through the vessel outlet and ultimately to a substrate reaction chamber. The vessel typically includes isolation valves for fluidly isolating the contents of the vessel from the vessel exterior. One isolation valve may be provided upstream of the vessel inlet, and another isolation valve may be provided downstream of the vessel outlet. The delivery vessel of some embodiments comprises, consists essentially of, or consists of a sublimator. As such, wherever a “delivery vessel” is mentioned herein, a sublimator (such as a “solid source chemical sublimator”) is also expressly contemplated.

Chemical vapor deposition (CVD) is a known process in the semiconductor industry for forming thin films of materials on substrates such as silicon wafers. In CVD, reactant vapors (including “precursor gases”) of different reactant chemicals are delivered to one or more substrates in a reaction chamber. In many cases, the reaction chamber includes only a single substrate supported on a substrate holder (such as a susceptor), with the substrate and substrate holder being maintained at a desired process temperature. In typical CVD processes, mutually reactive reactant vapors react with one another to form thin films on the substrate, with the growth rate being related to the temperature and the amounts of reactant gases.

In some applications, the reactant gases are stored in a reactant delivery vessel. In such applications, the reactants are often gaseous at standard pressures and temperatures of around 1 atmosphere and room temperature. Examples of such gases include nitrogen, oxygen, hydrogen, and ammonia. However, in some cases, the vapors of source chemicals (“precursors”) that are liquid or solid (e.g., hafnium chloride, hafnium oxide, zirconium dioxide, etc.) at standard pressure and temperature are used. For some solid substances (referred to herein as “solid source precursors”, “solid chemical reactants”, or “solid reactants”), the vapor pressure at room temperature is so low that they are typically heated and/or maintained at very low pressures to produce a sufficient amount of reactant vapor for the reaction process. Once vaporized (e.g., sublimed or evaporated), keeping the vapor phase reactant at or above the vaporizing temperature through the processing system can prevent undesirable condensation in the valves, filters, conduits, and other components associated with delivering the vapor phase reactants from one location to another, for example from the delivery vessel to the reaction chamber. Vapor phase reactants from such naturally solid or liquid substances are useful for chemical reactions in a variety of other industries.

Atomic layer deposition (ALD) is another known process for forming thin films on substrates. In many applications, ALD uses a solid and/or liquid source chemical as described herein. ALD is a type of vapor deposition wherein a film is built up through self-saturating reactions performed in cycles. The thickness of the film is determined by the number of cycles performed. In an ALD process, gaseous reactants are supplied, alternatingly and/or repeatedly, to the substrate or wafer to form a thin film of material on the wafer. One reactant adsorbs in a self-limiting process on the wafer. A different, subsequently pulsed reactant reacts with the adsorbed material to form a single molecular layer of the desired material. Decomposition may occur through mutual reaction between the adsorbed species and with an appropriately selected reagent, such as in a ligand exchange or a gettering reaction. In some ALD reactions, no more than a molecular monolayer forms per cycle. Thicker films are produced through repeated growth cycles until the target thickness is achieved. In some ALD reactions, mutually reactive reactants are kept separate in the vapor phase with intervening removal processes between substrate exposures to different reactants.

Remote refill vessels and/or delivery vessels may be supplied with gas lines extending from the inlet and outlet, isolation valves on the lines, and fittings on the valves, the fittings being configured to connect to the gas flow lines of the remaining substrate processing platform. It is desirable to provide a number of additional heaters for heating the various valves and gas flow lines between the reactant delivery vessel and the reaction chamber, to prevent the reactant liquid or vapor from solidifying or condensing and depositing on such components. Accordingly, the gas and/or liquid conveying components between the remote refill vessel, delivery vessel and the reaction chambers may be maintained at a temperature above the vaporization/condensation/sublimation temperature of the reactant.

Multiple remote refill vessels may be included for filling the delivery vessel with source precursor as described herein. Conventionally, delivery vessels are removed and refilled from a substrate processing platform, which can lead to downtime and a loss of wafer production. The remote refill vessels can reduce a need to replace or refill a sublimator. Instead, the remote refill vessels can be used to automatically and/or continuously supply a delivery vessel with chemicals such as source precursor. A remote refill vessel system may include one or more remote refill vessels. Furthermore, remote refill vessels in accordance with embodiments herein can be disposed in a location remote to the substrate processing platform, for example, in a sub-fab, or other remote location. Thus, remote refill vessels volumes are not subject to size limitations of vessels disposed on the substrate processing platform.

In some examples, remote refill vessel may be disposed in a location that is spaced apart from a substrate processing platform (or “tool”). For example, a remote refill vessel may be located in another room from the substrate processing platform, across a cleanroom from the substrate processing platform, adjacent to the substrate processing platform or in a sub-fab. For the purposes of this disclosure a “sub-fab” is an area underneath a substrate processing platform. In some examples, it may be built into the floor of a cleanroom, in a building level lower than the level on which the substrate processing platform is disposed or may comprise a lower portion of substrate processing platform.

Having one or more remote refill vessels removed from a substrate processing platform system for refilling, the remote refill vessel reduce labor, downtime and safety excursions associated with replacing delivery vessels. Additional features are described herein with reference to various configurations.

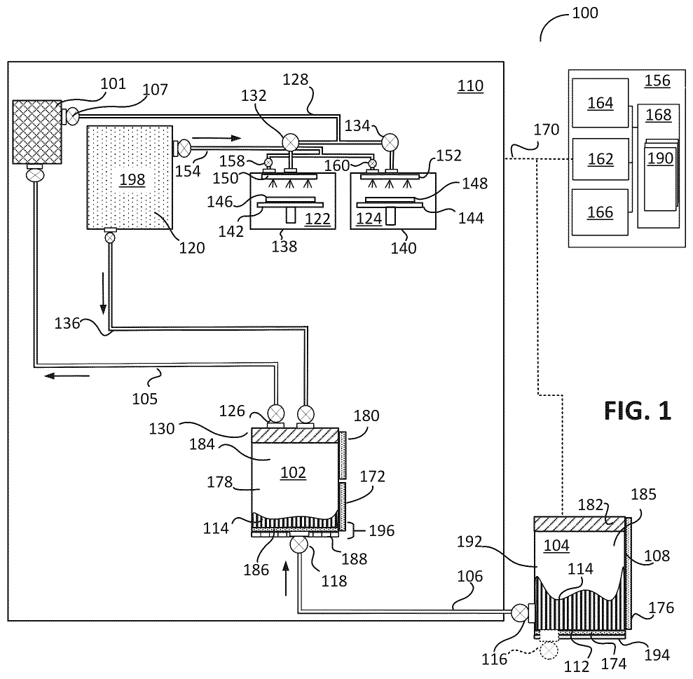

FIG. 1 is a schematic diagram illustrating an example substrate processing system 100 that includes a delivery vessel 102 disposed on substrate processing platform 110. Substrate processing platform 110 includes one or more reaction chambers 138 and 140 including respective reaction chambers 122 and 124. Reaction chambers 138 and 140 include respective susceptors 142 and 144 to hold respective substrates 146 and 148 during processing. Substrate processing platform 110 includes gas distribution systems 150 and 152 to distribute one or more reactants to respective surfaces of substrates 146 and 148. Substrate processing platform 110 may include a vacuum source (not shown) for controlling vacuum pressure in one or more of reaction chambers 122 and 124. A reactant source may feed a gas-phase reactant, generated from a solid precursor source delivery vessel 102 into gas-phase reaction chambers 138 and/or 140. A carrier gas source 120 may also be fluidly coupled to reaction chambers 122 and 124 via chemical delivery line 154 and valves 158 and 160.

The solid source delivery vessel 102 may contain a precursor or source chemical (e.g., chemical 114), which may be solid under standard conditions (i.e., room temperature and atmospheric pressure).

In an example, delivery vessel 102 may be coupled to a remote refill vessel 104. Remote refill vessel 104 may be located distant laterally, above or below delivery vessel 102 and/or substrate processing platform 110. For example, remote processing vessel 104 may be disposed in a sub-fab located under substrate processing platform 110. Remote refill vessel 104 may comprise a bulk refill container and can be coupled to the delivery vessel 102 via a chemical delivery line 106.

Chemical delivery line 106 may extend between outlet valve 116 of remote refill vessel 104 and inlet valve 118 of delivery vessel 102. Inlet valve 118 may be disposed on a bottom portion 196 of delivery vessel 102. Outlet valve 116 may be disposed in a lower portion near or on the bottom portion 112 of remote refill vessel 104. Valves 116 and 118 may be configured to control the flow of chemical 114 from remote refill vessel 104 to delivery vessel 102.

Remote refill vessel 104 may have a larger chemical capacity within housing 108 than delivery vessel 102 as it may not be restrained by size restrictions within the substrate processing platform 110. For example, remote refill vessel 104 may have at least 1.5×, 2×, 3×, 4×, 5×, 10×, or 20× the capacity of delivery vessel 102. Other capacities are possible and claimed subject matter is not limited in this regard.

In an example, remote refill vessel 104 may contain refill chemical 114 comprising a precursor or source chemical, which may be solid under standard conditions (i.e., room temperature and atmospheric pressure). Remote refill vessel 104 may pass chemical 114 therein to delivery vessel 102 via chemical delivery line 106. Remote refill vessel 104 may be equipped to melt and/or liquify chemical 114 before passing through the chemical delivery line 106. In an example, remote refill vessel 104 may heat chemical 114 to a temperature above a melting point to prevent solidification in chemical line 106 to facilitate flow through the line and prevent clogging. Remote refill vessel 104 may have one or more heating devices 174 and/or 176 (e.g., heaters and/or valve ports) adapted to heat chemical 114 to at least a melting point temperature. Heating devices 174 and/or 176 may be proximate to or disposed on an exterior of remote refill vessel 102. Heating devices 174 and/or 176 may be in thermal communication with lid 182 and/or housing 108. For example, heating device 174 may be positioned proximate or coupled to bottom portion 112 of remote refill vessel 104 and heating device 176 may be positioned proximate or coupled to sidewalls 192 of housing 108. Lid 182 and housing 108 may be made of thermally conductive material (e.g., stainless steel) and may be configured to transfer heat from heating devices 174 and/or 176 to lid 182 and/or an inner volume 185 of remote refill vessel 104. Heating devices 174 and/or 176 may heat chemical 114 to a temperature sufficient to liquify it and to prevent solidification on lid 182 and sidewalls 192 during a refilling operation. Heating devices 174 and/or 176 may heat chemical 114 to a temperature above the melting point to further avoid solidification in chemical delivery line 106 during transfer to delivery vessel 102. This may facilitate transferring chemical 114 via chemical delivery line 106 to delivery vessel 102 with minimal clogging. In an example, chemical delivery line 106 outlet valve 116 may be disposed lower in remote refill vessel 104 or at the bottom portion 112 of the vessel 104. Heating devices 174 and/or 176 may comprise any of a variety of heating devices (e.g., heaters, heating jackets, heating blocks, and/or radial heater) known to those of skill in the art and claimed subject matter is not limited in this regard.

Remote refill vessel 104 may be configured to operate at an operating temperature. For example, the operating temperature may be determined based on a desired melting/liquification rate of the chemical precursor/reactant. In some examples, the operating temperature is in the range of about 10° C. to about 500° C. Other temperature ranges are possible and claimed subject matter is not limited in this regard.

In an example, delivery vessel 102 may be thermally coupled to one or more heating devices 172, 180 and/or 186 disposed on exterior of housing 178. Heating device 186 may be disposed on a bottom portion 196 of delivery vessel 102. Heating devices 180 and 172 may be disposed on a sidewall of housing 178. Such heating devices serve to control or adjust the temperature of chemical 114 during refilling operations, material processing operations and storage of chemical 114.

In an example, as chemical 114 enters delivery vessel 102 via valve 118, it may be kept at a temperature above a melting point and/or above a temperature it was heated to by remote refill vessel 104 to prevent solidification during the refilling operation. Heating devices 172, 180 and/or 186 may be adapted to continuously apply heat sufficient to at least maintain chemical 114 in liquid phase at the bottom portion 196 of delivery vessel 102 until refilling is complete. Housing 178 and/or lid 130 may be configured to transfer heat from heating devices 172, 180 and 186 to inner volume 184 to heat chemical 114. Heating devices 172, 180 and 186 may comprise any of a variety of heating devices (e.g., heaters, heating jackets, heating blocks, and/or radial heater) known to those of skill in the art and claimed subject matter is not limited in this regard.

Delivery vessel 104 may be configured to operate at an operating temperature based on a desired maintenance of chemical precursor/reactant, chemical 114 in liquid state. In some examples, the operating temperature is in the range of about 10° C. to about 500° C. Other temperature ranges are possible and claimed subject matter is not limited in this regard.

Once a refilling operation is complete, chemical 114 may form a solid at the bottom of delivery vessel 102 and may be stored there until a material processing operation. Chemical 114 may be cooled to a solidification temperature by a cooling device 188 coupled to delivery vessel 102 to maintain a temperature at the base of delivery vessel 102 sufficient to maintain chemical 114 in solid phase for storage. Cooling device 188 may comprise any of a variety of cooling devices including but not limited to a chill plate, cooling coils, variable pitch cooling coils, a cooling jacket, cooling fans, a Peltier cooler or integrated coolant channels circulating coolant or the like or any combination thereof. Alternatively, chemical 114 may be stored in a different form such as liquid. Heating devices 172, 180 and/or 186 may maintain chemical 114 in a liquid state at a temperature below the vaporization and/or sublimation point to store chemical 114 prior to a material processing operation.

In an example, during a material processing operation heating devices 172, 180 and/or 186 may be configured to heat chemical 114 to a temperature sufficient to change the phase of chemical 114, from liquid or solid, for example, by vaporizing and/or sublimating chemical 114. Such phase change may be brought about by changing the pressure applied to chemical 114 alone or in addition to changing the temperature. Once vaporized or sublimed, chemical 114 may be transported via chemical delivery line 105 to an accumulator 101. From accumulator 101, chemical 114 may continue via valve 107 through chemical delivery line 128 to reaction chambers 122 and/or 124 for substrate processing.

Accumulator 101 may reduce particle concerns as a refill pipeline (e.g., chemical delivery line 106) does not directly open to reaction chambers 122 and/or 124 and can have higher tolerance to solid residues. In an example, an accumulator 101 may comprise a chamber or vessel designed to control particle formation in a precursor gas such as chemical 114. Accumulator 101 may be located downstream of delivery vessel 102 and upstream of reaction chambers 122 and/or 124. The accumulator 101 chamber may regulate the flow of chemical 114 gas and may maintain a consistent pressure and flow rate throughout processing of the substrate. Thus, accumulator 101 may reduce particles in chemical 114 due to controlled temperature and/or flow because variations in temperature, pressure or flow rate can lead to particle formation or other process instabilities. In other examples, accumulator 101 may reduce particles using other mechanical and thermal means to prevent, capture and/or remove particles from forming in chemical 114. Accumulator 101 helps to ensure substrate processing is high-quality and consistent.

A carrier gas source 120 may be coupled to delivery vessel 102 via chemical delivery line 136 and may contain carrier gas 198. When introduced into delivery vessel 102, the carrier gas 198 helps transport vaporized and/or sublimed chemical 114 reactants through via outlet valve 126 through chemical delivery line 105 to accumulator 101, and further on to substrate reaction chamber 122 and/or 124. Chemical delivery line 128 may comprise valves 132 and 134 for controlling fluid communication of chemical 114 and/or carrier gas 198 from accumulator 101 to respective reaction chambers 122 and 124.

During material processing, delivery vessel 102 may be configured to operate at an operating temperature based on a desired subliming rate of chemical 114 chemical precursor/reactants. In some examples, the operating temperature is in the range of about 10° C.-500° C. Other temperature ranges are possible and claimed subject matter is not limited in this regard.

Once depleted of chemical 114, delivery vessel 102 may be refilled from remote refill vessel 104, repeating the above process until remote refill vessel 104 is depleted. In some examples, it may not be necessary to completely deplete delivery vessel 102 of chemical 114 prior to refilling from remote refill vessel 104.

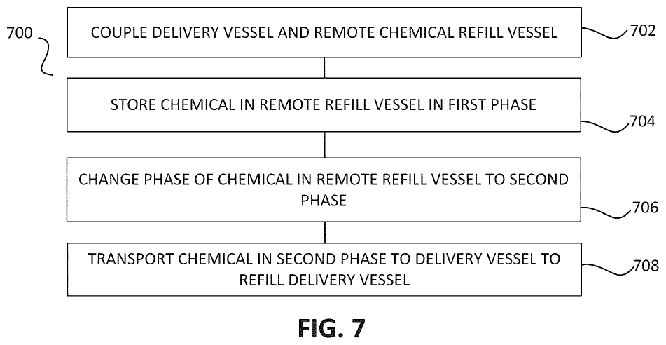

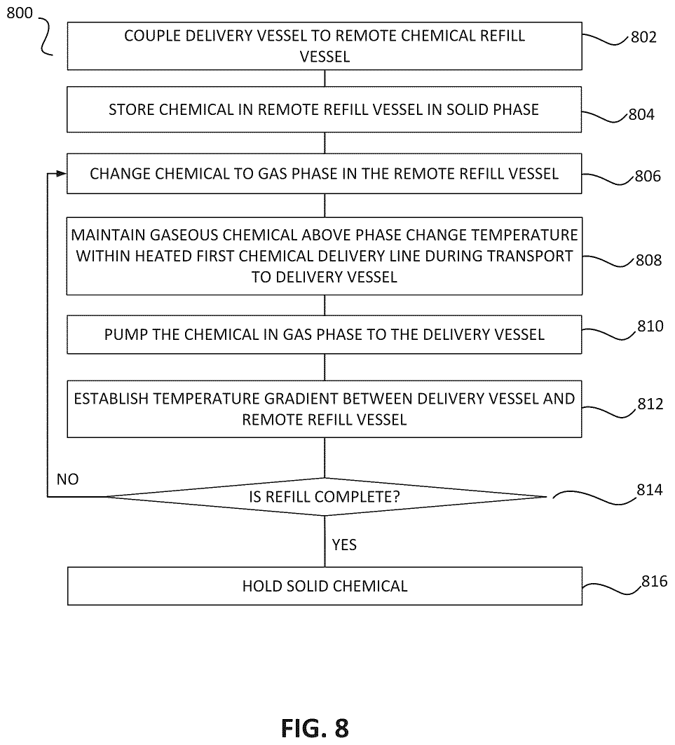

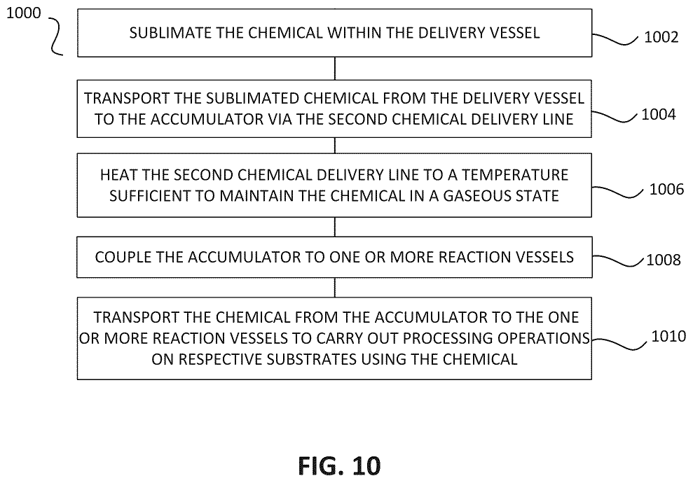

In the illustrated example controller 156 includes a device interface 162, a processor 164, a user interface 166, and a memory 168. The device interface 162 connects the processor 164 to the wired or wireless link 170. The processor 164 may be operably connected to the user interface 166 (e.g., to receive user input and/or provide user output therethrough) and may be disposed in communication with the memory 168. The memory 168 includes a non-transitory machine-readable medium having a plurality of program modules 190 recorded thereon containing instructions that, when read by the processor 164, cause the processor 164 to execute certain operations. Among the operations are operations of a material layer deposition method and methods for refilling a delivery vessel 102 (shown in FIG. 7, FIG. 8 and FIG. 10), as will be described. As will be appreciated by those of skill in the art in view of the present disclosure, the controller 156 may have a different arrangement in other examples and remain within the scope of the present disclosure. In some embodiments, the electronics and/or computer elements for use in controlling one or more of heaters, cooing devices, valves, reaction chamber 122, reaction chamber 124, accumulator 101, delivery vessel 102 and/or remote refill vessel 104 can be found elsewhere in the system. For example, central controllers may control both apparatus of the one or more chambers themselves as well as control the valves that connect to the various vessels and any associated heaters. One or more valves may be used to control the flow of gas throughout substrate processing system 100.

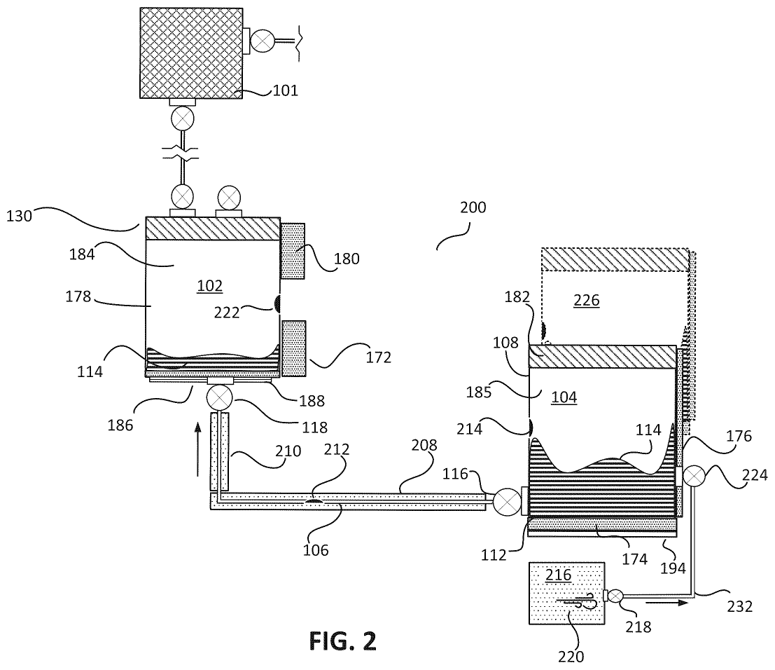

FIG. 2 is a schematic diagram illustrating an example refill subassembly 200 of substrate processing system 100 depicted in FIG. 1. Refill subassembly 200 includes delivery vessel 102 coupled to remote refill vessel 104 via chemical delivery line 106. Remote refill vessel 104 may be configured to maintain a temperature sufficient to store chemical 114 (e.g., precursor) in a solid state prior to being liquified, sublimed or vaporized. During storage, before a refilling operation, bottom portion 112 of the remote refill vessel 104 may be at a relatively low temperature. Cooling device 194 may be adapted to cool bottom portion 112 and may comprise any of a variety of cooling devices including but not limited to a chill plate, cooling coils, variable pitch cooling coils, a cooling jacket, cooling fans, a Peltier cooler or integrated coolant channels circulating coolant or the like or any combination thereof.

In an example, heating devices 208 and/or 210 may be coupled to chemical delivery line 106 to maintain a “transport temperature” which may be a liquification temperature to prevent solidification during transport. Such a transport temperature may be equal to or above a phase change (e.g., liquification) temperature. Heating devices 208 and/or 210 may be wrapped around, coiled, envelop, or otherwise be disposed in close proximity to chemical delivery line 106. Heating devices 208 and/or 210 may comprise heater jackets or other heating devices known to those of skill in the art and claimed subject matter is not limited in this regard. Chemical delivery line 106 may be arranged to have very few angles or corners to discourage solidification of chemical 114. Valves, connection points and/or other interruptions in the chemical delivery line 106 may be minimized to the extent possible to offset a higher risk of solidification in chemical delivery line 106 due to the disposition of remote refill vessel 104 distant from (i.e., spaced apart) from substrate processing platform 110 (see FIG. 1).

In an example, the refilling process may be controlled manually and/or refill operations may be partially or fully automated using a variety of sensors for automated feedback control by a controller 156 (see FIG. 1). For example, sensor 222 may be disposed adjacent to or within an inner volume 184 of delivery vessel 102, sensor 212 may be disposed within or adjacent to chemical delivery line 106 and sensor 214 may be disposed adjacent to or within an inner volume 185 of remote refill vessel 104. Sensors 212, 214, and/or 222 may monitor a variety of physical phenomenon such as, for example, acoustics, vibration, chemicals, moisture, flow, light, pressure, force, density, temperature and/or presence, or the like or any combinations thereof. Sensors 212, 214, and/or 222 may, for example, monitor the temperature of chemical 114 in delivery vessel 102, chemical delivery line 106, or remote refill vessel 104, or a combination thereof. Sensors 212, 214, and/or 222 may generate sensor data based on the monitoring and send the sensor data to controller 156 (see, FIG. 1) via communication link 170 to adjust a monitored parameter (e.g., temperature). For example, based on the sensor data, controller 156 may adjust one or more of heating devices 172, 174, 176, 180, 186, 208, and/or 210 and/or cooling devices 188 and 194 or the like or a combination thereof to bring chemical 114 within a preset temperature threshold value.

In some examples, a carrier gas source 216 may be coupled to remote refill vessel 104 via chemical delivery line 232 and may supply carrier gas 220 to remote refill vessel 104.

In an example, one or more back-up remote refill vessels 226 may be co-located with remote refill vessel 104 to reduce downtime required to replace remote refill vessel 102 when depleted. When remote refill vessel 104 needs to be replaced, back-up remote refill vessels 226 may be quickly coupled to delivery vessel 102 via valve 116 to chemical delivery line 106 (or via a different chemical delivery line) to avoid downtime waiting for remote refill vessel 104 to be removed and replaced. Alternatively, back-up remote refill vessels 226 may be coupled to remote refill vessel 104 to refill vessel 226 at other opportune idle times, such as between refill operations or during upstream events requiring downtime on the substrate processing platform 110. Valves 218 and 224 may control the flow of carrier gas 220. Carrier gas 220 may increase pressure within remote refill vessel 104 to assist transport of the liquified chemical 114.

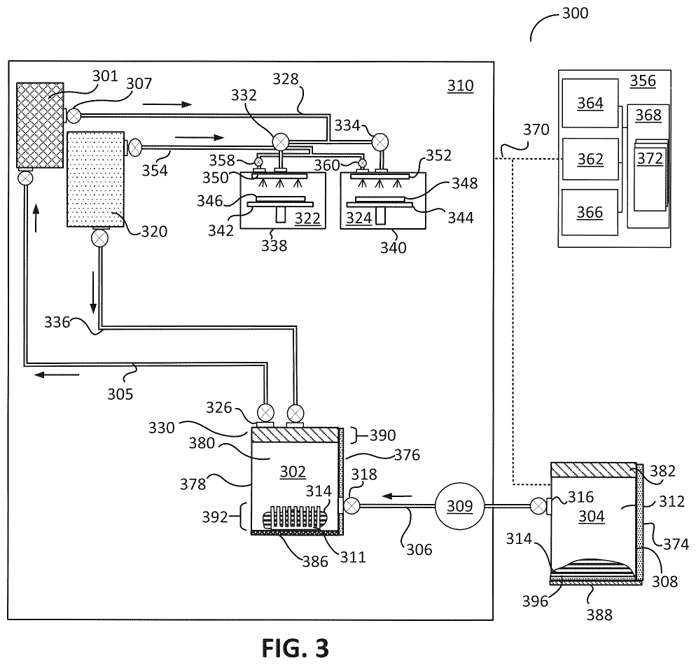

FIG. 3 is a schematic illustrating an example substrate processing system 300 that includes a delivery vessel 302 disposed on substrate processing platform 310. Substrate processing platform 310 includes one or more reaction chambers 338 and 340 including respective reaction chambers 322 and 324. Reaction chambers 338 and 340 include respective susceptors 342 and 344 to hold respective substrates 346 and 348 during processing. Substrate processing platform 310 includes gas distribution systems 350 and 352 to distribute one or more reactants to respective surfaces of substrates 346 and 348. Substrate processing platform 310 may include a vacuum source (not shown) for controlling vacuum pressure in one or more of reaction chambers 322 and 324. A reactant source such as accumulator 301 may feed a gas-phase reactant (e.g., chemical 314) received from delivery vessel 302 into gas-phase reaction chambers. Reaction chambers 338 and/or 340 may be gas-phase reaction chambers. In an example, solid source delivery vessel 302 may sublime gas-phase chemical 314 from solid precursor. Chemical 314 may comprise a chemical reactant such as source chemicals or precursor including but not limited to HfCl4, ZrCl4, AlCl3, TaF5, MoF5, SiI4, MoCl5, MoO2Cl2, WCl5 or the like or combinations thereof. Chemical 314 may be solid under standard conditions (i.e., room temperature and atmospheric pressure).

A carrier gas source 320 may be coupled to delivery vessel 302 via chemical delivery line 336 and may hold a carrier gas. Carrier gas source 320 may be fluidly coupled to reaction chambers 322 and 324 via chemical delivery line 354 and valves 358 and 360. When introduced into delivery vessel 302, the carrier gas helps transport vaporized and/or sublimed chemical 314 through chemical delivery line 305 to accumulator 301 via valve 326. In accumulator 301, temperature, pressure and/or flow rate may be precisely controlled to reduce particle formation in chemical 314. Chemical 314 is then transported to substrate reaction chamber 322 and/or 324 via outlet valve 307 and chemical delivery line 328. Chemical delivery line 328 may comprise valves 332 and 334 for controlling fluid communication of chemical 314 and/or carrier gas from delivery vessel 302 to respective reaction chambers 322 and 324.

In an example, delivery vessel 302 may be coupled to a remote refill vessel 304 via a chemical delivery line 306. Delivery vessel 302 may receive chemical 314 in gas phase via chemical delivery line 306 from remote refill vessel 304. Chemical delivery line 306 may be coupled to delivery vessel 302 at a lower portion 392 of delivery vessel 302. In other examples, chemical delivery line may be disposed in a top portion 390, for example, in lid 330.

Remote refill vessel 304 may be located distant laterally, above or below delivery vessel 302 and/or substrate processing platform 310, for example in a sub-fab located beneath substrate processing platform 310. Remote refill vessel 304 may contain refill chemical 314 comprising a precursor or source chemical, which may be solid under standard conditions (i.e., room temperature and atmospheric pressure). Remote refill vessel 304 may be a bulk refill container that may have a larger chemical capacity within housing 308 than delivery vessel 302 as it may not be restrained by dimension restrictions associated with substrate processing platform 310. For example, remote refill vessel 304 may have at least 1.5×, 2×, 3×, 4×, 5×, 10×, or 20× the capacity of delivery vessel 302. Other capacities are possible and claimed subject matter is not limited in this regard.

In an example, chemical delivery line 306 may extend between outlet valve 316 of remote refill vessel 304 and inlet valve 318 of delivery vessel 302. Outlet valve 316 and inlet valve 318 may control fluid communication of chemical 314 from remote refill vessel 304 to delivery vessel 302. Remote refill vessel 304 may be configured to store chemical 314 between refill operations. A cooling device 388 may be coupled to a bottom portion of remote refill vessel 304. Cooling device 388 may cool bottom surface portion 396 so as to maintain chemical 314 in solid form prior to sublimation. Cooling device 388 may comprise a chill plate, cooling coils, variable pitch cooling coils, a cooling jacket, cooling fans, a Peltier cooler or integrated coolant channels circulating coolant or the like or any combination thereof.

In an example, remote refill vessel 304 may be equipped to vaporize (e.g., sublimate, evaporate) chemical 314 and may subsequently pass vaporized or sublimated chemical 314 to delivery vessel 302 via chemical delivery line 306. In an example, remote refill vessel 304 may be proximate a heating device 374 disposed exterior to and in thermal communication with lid 382 and/or housing 308. Housing 308 may be made of a thermally conductive material (e.g., stainless steel) and may be configured to transfer heat from heating device 374 to a lid 382 and/or an inner volume 312 of housing 308. Heating device 374 may be configured to heat chemical 314 to a temperature sufficient to change the phase of chemical 314, such as to vaporize and/or sublimate chemical 314 in order to transfer chemical 314 via chemical delivery line 306 to delivery vessel 302. Heating device 374 may comprise any of a variety of heating devices known to those of skill in the art such as heaters, heating jackets, heating blocks, and/or radial heater, or the like or combinations thereof and claimed subject matter is not limited in this regard.

In an example, remote refill vessel 304 may be configured to operate at a selected temperature. For example, the operating temperature may be determined based on a desired subliming rate of the chemical precursor/reactant. In some examples, the operating temperature is in the range of about 10° C. to about 500° C. The selected operating temperature may depend, of course, upon the chemical to be vaporized or sublimed. Other temperature ranges are possible and claimed subject matter is not limited in this regard.

In an example, chemical delivery line 306 is coupled to a pump 309. Pump 309 may be a mechanical pump, such as a high flow sublimation/mechanical hybrid pump, or any of a variety of pumps known to those of skill in the art operable to pump a liquid or gaseous substance under high temperature and/or high-pressure conditions. After sublimation of chemical 314 in remote refill vessel 302, pump 309 may direct chemical 314 from remote refill vessel 304 to delivery vessel 302. During processing, cooling device 386 and/or one or more cooling projections 311 may maintain a lower temperature within inner volume 380 of delivery vessel 302 than within inner volume 312 of remote refill vessel 304, creating a temperature gradient between the two vessels. This gradient facilitates the efficient transfer of chemical 314 from remote refill vessel 304 to delivery vessel 302, with the aid of pump 309. Cooling projections 311 may comprise any of a variety of active or passive cooling devices such as a cooling device comprising one or more projecting members that may be fingerlike projections, fins, or the like or combinations thereof. Cooling projections 311 may be configured to actively or passively cool by any of a variety of mechanisms, such as by passive heat exchange, phase-change cooling, liquid cooling, thermoelectric cooling, or heat-pipe cooling, or the like or a combination thereof.

In an example, delivery vessel 302 may be proximate and/or thermally coupled to one or more heating devices 376 disposed on an exterior of housing 378 and/or lid 330. Such heating devices serve to control or adjust the temperature of chemical 314 during refilling operations, material processing operations and storage of chemical 314. Heating device 376 may comprise any of a variety of heating devices known to those of skill in the art such as heaters, heating jackets, heating blocks, and/or radial heaters, or the like or combinations thereof and claimed subject matter is not limited in this regard. Likewise, delivery vessel 302 may be proximate and/or thermally coupled to one or more cooling devices 386 disposed in an interior and/or on an exterior of housing 378. Such cooling devices 386 may comprise any of a variety of cooling devices, such as cooling members (e.g., cold fingers or cooling projections), a chill plate, cooling coils, variable pitch cooling coils, a cooling jacket, cooling fans, a Peltier cooler or integrated coolant channels circulating coolant, or the like or combinations thereof and claimed subject matter is not limited in this regard.

The temperature of delivery vessel 302 bottom portion 392 may be cooled by cooling device 386 and/or cooling projections 311 to a lower temperature than incoming chemical delivery line 306, sidewalls of housing 378 or lid 330 of delivery vessel 302. Chemical 314 may solidify in the area contacting or proximate cooling device 386 and/or cooling projections 311 near bottom portion 392 of delivery vessel 302. During refill, chemical 314 will form a solid within delivery vessel 302. Cooling device 386 and/or cooling projections 311 may maintain a temperature in bottom portion 392 of delivery vessel 302 sufficient to maintain chemical 314 in solid phase prior to material processing operations.

In an example, during a material processing operation, heating device 376 may be configured to heat chemical 314 to a temperature sufficient to change the phase of chemical 314, such as to vaporize and/or sublimate chemical 314. Once vaporized or sublimed, chemical 314 may be transported via chemical delivery line 305 to accumulator 301 and onto reaction chambers 322 and/or 324 for substrate processing.

During material processing, delivery vessel 302 may be configured to operate at a selected temperature based on a desired subliming rate of chemical 314 precursor/reactants. In some examples, the operating temperature is in the range of about 10° C. to about 500° C. Other temperature ranges are possible and claimed subject matter is not limited in this regard. Once depleted of chemical 314, delivery vessel 302 may be refilled from remote refill vessel 304. It may not be necessary to completely deplete delivery vessel 302 of chemical 314 prior to refilling from remote refill vessel 304.

In the illustrated example controller 356 includes a device interface 362, a processor 364, a user interface 366, and a memory 368. The device interface 362 connects the processor 364 to the wired or wireless link 370. The processor 364 may be operably connected to the user interface 366 (e.g., to receive user input and/or provide user output therethrough) and may be disposed in communication with the memory 368. The memory 368 includes a non-transitory machine-readable medium having a plurality of program modules 372 recorded thereon containing instructions that, when read by the processor 364, cause the processor 364 to execute certain operations. Among the operations are operations of a material layer deposition method and methods for refilling a delivery vessel 302 (shown in FIG. 7, FIG. 8 and FIG. 10), as will be described. As will be appreciated by those of skill in the art in view of the present disclosure, the controller 356 may have a different arrangement in other examples and remain within the scope of the present disclosure.

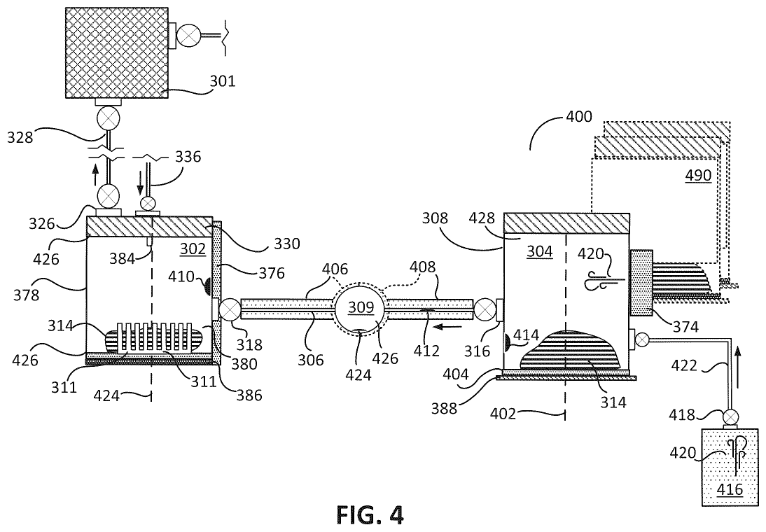

FIG. 4 is a schematic diagram illustrating an example refill subassembly 400 of substrate processing system 300 depicted in FIG. 3. Refill subassembly 400 includes delivery vessel 302 coupled to remote refill vessel 304 via chemical delivery line 306. Remote refill vessel 304 may be configured to maintain a temperature sufficient to store chemical 314 (e.g., precursor) in a solid state prior to being sublimed or vaporized. Base 404 of the remote refill vessel 304 may be at a relatively low temperature (e.g., to maintain the precursor as a solid). A carrier gas source 416 may be coupled to remote refill vessel 304 via chemical delivery line 422 and may supply carrier gas 420 to remote refill vessel 304. Valve 418 may control the flow of carrier gas 420. Carrier gas 420 may assist transport of the sublimated chemical 314 from the remote refill vessel 304 to delivery vessel 302.

In an example, heaters 406 and 408 may be coupled to chemical delivery line 306 to maintain a “transport temperature” which may be a vaporization temperature to prevent condensation during transport. Such vaporization temperatures may be equal to or above a phase change temperature (e.g., a sublimation temperature) of chemical 314. Heaters 406 and 408 may comprise heater jackets or other heating devices known to those of skill in the art and claimed subject matter is not limited in this regard. Heaters 406 and 408 may be wrapped around, coiled, envelop, or otherwise be disposed in close proximity to chemical delivery line 306. Heaters 406 and 408 may be disposed adjacent to pump 309 and/or may envelop pump 309. Chemical delivery line 306 may have very few angles or corners to discourage condensation. Valves, connection points and/or other interruptions in the chemical delivery line 306 may be minimized to the extent possible to offset a higher risk of condensation in chemical delivery line 306 due to the disposition of remote refill vessel 304 distant from (i.e., spaced apart) from substrate processing platform 310 (see FIG. 3).

In an example, one or more back-up remote refill vessels 490 may be co-located with remote refill vessel 304 to reduce downtime required to replace remote refill vessel 304 when depleted. When remote refill vessel 304 needs to be replaced, back-up remote refill vessels 490 may be quickly coupled to delivery vessel 302 via chemical delivery line 306 (or via a different chemical delivery line) to avoid downtime waiting for remote refill vessel 304 to be removed and replaced. Alternatively, back-up remote refill vessels 490 may be coupled to remote refill vessel 304 to refill vessel 304 at other opportune idle times, such as between refill operations or upstream events requiring downtime on the substrate processing platform 310.

In an example, the refilling process may be controlled manually and/or refill operations may be partially or fully automated using a variety of sensors for automated feedback control by a controller 356. For example, sensor 410 may be disposed adjacent to or within an inner volume 380 of delivery vessel 302, sensor 412 may be disposed within or adjacent to chemical delivery line 306, sensor 424 may be disposed adjacent to or within an interior portion 426 of pump 309 and sensor 414 may be disposed adjacent to or within an inner volume 428 of remote refill vessel 304. Sensors 410, 412, 414, and/or 424 may monitor a variety of physical phenomenon such as, for example, acoustics, vibration, chemicals, moisture, flow, light, pressure, force, density, temperature and/or presence, or the like or any combinations thereof. Sensors 410, 412, 414, and/or 424 may, for example, monitor a temperature gradient between remote refill vessel 304 and delivery vessel 302 and/or monitor a temperature of the chemical 314 disposed in at least one of the chemical delivery line 306, pump 309, delivery vessel 302 or the remote refill vessel 304, or a combination thereof. Sensors 410, 412, 414, and/or 424 may alternatively or additionally monitor a temperature and/or pressure of or within chemical delivery line 306, pump 309, delivery vessel 302 and/or remote refill vessel 304, or a combination thereof. Sensors 410, 412, 414, and/or 424 may generate sensor data based on the monitoring and send the sensor data to controller 356 (see, FIG. 3) to adjust the monitored devices to change a monitored parameter (e.g., temperature, pressure, and/or pump cycle time). For example, controller 356 may adjust one or more of heating devices 374, 376, 406 and/or 408, cooling projections 311, cooling devices 386 and 388, or pump 309 or a combination thereof based on the sensor data.

In some examples, the electronics and/or computer elements for use in controlling one or more of reaction chamber 322, reaction chamber 324, delivery vessel 302, pump 309 and/or remote refill vessel 304 may be found elsewhere in the system. For example, central controllers may control both apparatus of the one or more chambers themselves as well as control the valves that connect to the various vessels and any associated heating or cooling devices. One or more valves may be used to control the flow of gas throughout substrate processing system 300.

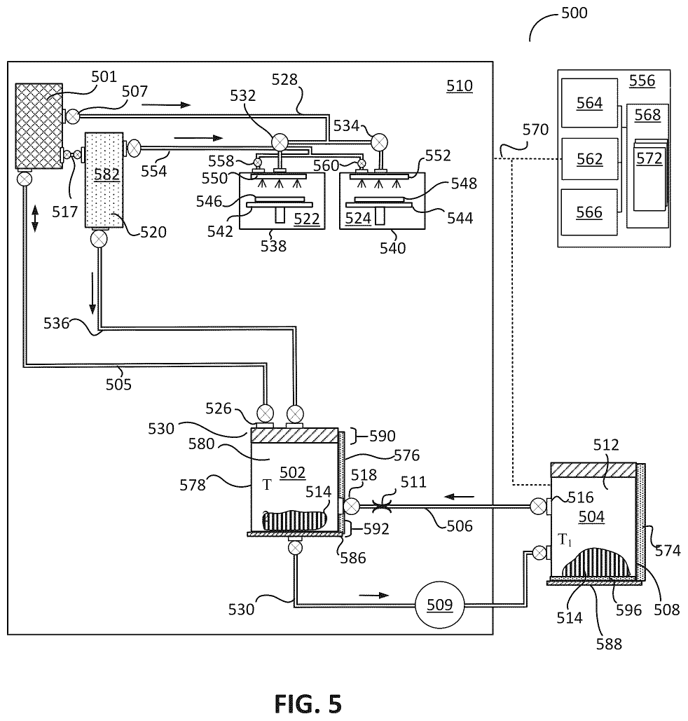

FIG. 5 is a schematic illustrating an example substrate processing system 500 that includes a delivery vessel 502 disposed on substrate processing platform 510. Substrate processing platform 510 includes one or more reaction chambers 538 and 540 including respective reaction chambers 522 and 524. Reaction chambers 538 and 540 include respective susceptors 542 and 544 to hold respective substrates 546 and 548 during processing. Substrate processing platform 510 includes gas distribution systems 550 and 552 to distribute one or more reactants to respective surfaces of substrates 546 and 548. Substrate processing platform 510 may include a vacuum source (not shown) for controlling vacuum pressure in one or more of reaction chambers 522 and 524. A reactant source such as accumulator 501 may feed a gas-phase reactant (e.g., chemical 514) received from delivery vessel 502 into gas-phase reaction chambers. Reaction chambers 538 and/or 540 may be gas-phase reaction chambers. In an example, solid source delivery vessel 502 may sublime gas-phase chemical 514 from solid precursor. Chemical 514 may comprise a chemical reactant such as source chemicals or precursor including but not limited to HfCl4, ZrCl4, AlCl3, TaF5, MoF5, SiI4, MoCl5, MoO2Cl2, WCl5 or the like or combinations thereof. Chemical 514 may be solid under standard conditions (i.e., room temperature and atmospheric pressure).

At least one carrier gas source 520 may be coupled to delivery vessel 502 via chemical delivery line 536 and may hold a carrier gas. Carrier gas source 520 may be fluidly coupled to reaction chambers 522 and 524 via chemical delivery line 554 and valves 558 and 560. When introduced into delivery vessel 502, the carrier gas helps transport vaporized and/or sublimed chemical 514 through chemical delivery line 505 to accumulator 501 via valve 526. In accumulator 501, temperature, pressure and/or flow rate may be precisely controlled to reduce particle formation in chemical 514. Chemical 514 is then transported to substrate reaction chamber 522 and/or 524 via outlet valve 507 and chemical delivery line 528. Chemical delivery line 528 may comprise valves 532 and 534 for controlling fluid communication of chemical 514 and/or carrier gas from delivery vessel 502 to respective reaction chambers 522 and 524. Accumulator 501 may further be coupled to gas source 520 via chemical delivery line 517.

In an example, delivery vessel 502 may be coupled to a remote refill vessel 504 via a chemical delivery line 506. Delivery vessel 502 may receive chemical 514 in gas phase via chemical delivery line 506 from remote refill vessel 504. Remote refill vessel 504 may be located distant laterally, above or below delivery vessel 502 and/or substrate processing platform 510, for example in a sub-fab located beneath substrate processing platform 510. Remote refill vessel 504 may contain refill chemical 514 comprising a precursor or source chemical, which may be solid under standard conditions (i.e., room temperature and atmospheric pressure). Remote refill vessel 504 may be a bulk refill container that may have a larger chemical capacity within housing 508 than delivery vessel 502 as it may not be restrained by dimension restrictions associated with substrate processing platform 510. For example, remote refill vessel 504 may have at least 1.5×, 2×, 3×, 4×, 5×, 10×, or 20× the capacity of delivery vessel 502. Other capacities are possible and claimed subject matter is not limited in this regard.

Remote refill vessel 504 may be configured to store chemical 514 between refill operations. A cooling device 588 may be coupled to a bottom portion of remote refill vessel 504. Cooling device 588 may cool bottom surface portion 596 so as to maintain chemical 514 in solid form prior to sublimation. Cooling device 588 may comprise a chill plate, cooling coils, variable pitch cooling coils, a cooling jacket, cooling fans, a Peltier cooler or integrated coolant channels circulating coolant or the like or any combination thereof.

In an example, remote refill vessel 504 may be equipped to vaporize (e.g., sublimate, evaporate) chemical 514 and may subsequently pass vaporized or sublimated chemical 514 to delivery vessel 502. Transfer of chemical 514 may be by inert carrier gas flow in a closed loop by flowing fluids in compressive and expansive cycles.

In an example, first chemical delivery line 506 may extend between outlet valve 516 of remote refill vessel 504 and inlet valve 518 of delivery vessel 502. Outlet valve 516 and inlet valve 518 may control fluid communication of chemical 514 from remote refill vessel 504 to delivery vessel 502. Third chemical delivery line 530 may also be coupled between remote refill vessel 504 and delivery vessel 502 providing a closed-loop circuit with first chemical delivery line 506 between the delivery vessel and the remote refill vessel. Compressor pump 509 may be coupled to third chemical delivery line 530. In an example, inert gas 582 (e.g., Ar) may be introduced into the system used to prime the closed-loop circuit. Once introduced, inert gas supply may be closed off in order to start flowing the inert gas in the closed-loop between remote refill vessel 504 and delivery vessel 502 with the aid of compressor pump 509. Initial input of inert gas 582 may be for priming purposes only. In one example, inert gas 582 may be supplied by accumulator 501 via gas source 520. A restrictor 511 may be coupled to first chemical delivery line 506 upstream of the delivery vessel 502 to maintain inert gas 582 and gaseous chemical 514 at a first pressure, between the compressor pump 509 and the restrictor 511, that is higher than a second pressure within the delivery vessel 502. The restrictor 511 may be operable to open to expand inert gas 582 and gaseous chemical 514 into delivery vessel 502 to solidify chemical 514 within delivery vessel 502.

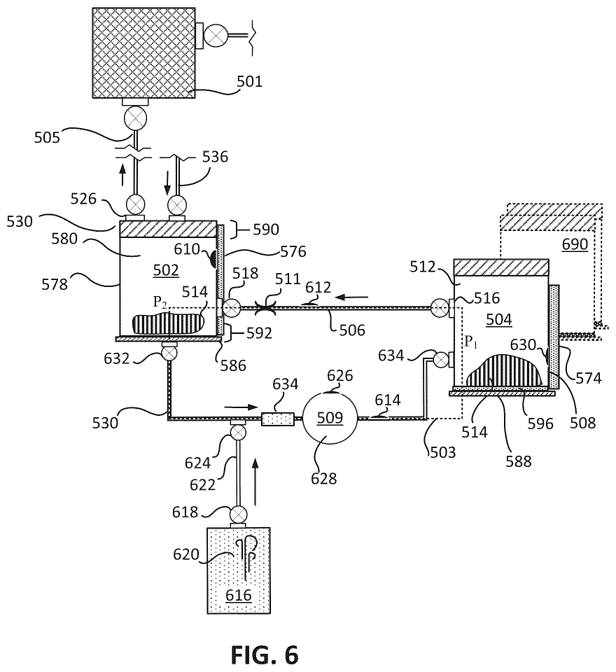

Turning now to FIG. 6 illustrating an example refill subassembly of the substrate processing system depicted in FIG. 5, wherein rather than introducing inert gas 582 via accumulator 501 into the closed-loop circuit 503, an inert gas source 620 is coupled directly to third chemical delivery line 530 via chemical deliver line 622. In this example, compressor pump 509 may be coupled to third chemical delivery line 530 upstream of inert gas source 620. Compressor pump 509 may direct inert gas 616 from gas source 620 to remote refill vessel 504. Inert gas 616 may be introduced into the system and used to prime the closed-loop circuit. Once inert gas 616 is introduced into closed-loop circuit 503, inert gas supply valves 618 and/or 624 may be closed in order to start flowing the inert gas 616 in closed-loop 503 between remote refill vessel 504 and delivery vessel 502 with the aid of compressor pump 509. Initial input of inert gas 616 may be for priming purposes only. Chemical 514 may also be present in third chemical line 530 after initial priming.

In an example, restrictor 511 is coupled to the first chemical delivery line 506 upstream of delivery vessel 502 to maintain inert gas 616 and gaseous chemical 514 at a first pressure P1, between compressor pump 509 and restrictor 511. The first pressure is higher than a second pressure, P2, within delivery vessel 502. Restrictor 511 may be operable to open to expand inert gas 616 and gaseous chemical 514 into delivery vessel 502 to solidify chemical 514 within delivery vessel 502.

In an example, to end refrigeration-type cycling in closed-loop circuit 503, outlet 632 of delivery vessel 502 may be closed while keeping inlet valve 518 open. With compressor pump 509 running pressure, P2, in delivery vessel 502 may increase such that it is higher than the pressure, P1, in remote refill vessel 504. Subsequently, inlet valve 518 and all valves of remote refill vessel 504 (e.g., valves 634 and 516) may be closed to turn off compressor pump 509.

Returning to FIG. 5, remote refill vessel 504 may be proximate a heating device 574 disposed exterior to and in thermal communication with housing 508. Housing 508 may be made of a thermally conductive material (e.g., stainless steel) and may be configured to transfer heat from heating device 574 to an inner volume 512 of housing 508. Heating device 574 may be configured to heat chemical 514 to a temperature sufficient to change the phase of chemical 514, such as to vaporize and/or sublimate chemical 514 in order to transfer chemical 514 to delivery vessel 502. Heating device 574 may comprise any of a variety of heating devices known to those of skill in the art such as heaters, heating jackets, heating blocks, and/or radial heater, or the like or combinations thereof and claimed subject matter is not limited in this regard.

In an example, remote refill vessel 504 may be configured to operate at a selected temperature. For example, the operating temperature may be determined based on a desired subliming rate of the chemical precursor/reactant. In some examples, the operating temperature is in the range of about 10° C. to about 500° C. The selected operating temperature may depend, of course, upon the chemical to be vaporized or sublimed. Other temperature ranges are possible and claimed subject matter is not limited in this regard.

In an example, chemical delivery line 506 is coupled to delivery vessel 502. During processing, a first temperature, T1, within inner volume 512 of remote refill vessel 504 may be greater than a second temperature, T2, within inner volume 580 of delivery vessel 502 creating a temperature gradient between the two vessels. This gradient facilitates the efficient transfer of chemical 514 from remote refill vessel 504 to delivery vessel 502 as well as vapor trap of chemical 514 within delivery vessel 502. Moreover, to maintain such a temperature gradient, delivery vessel 502 may be proximate and/or thermally coupled to one or more cooling devices 586 disposed in an interior and/or on an exterior of housing 578. Such cooling devices 586 may comprise any of a variety of cooling devices, such as cooling members (e.g., see cooling projections 311 in FIG. 3), a chill plate, cooling coils, variable pitch cooling coils, a cooling jacket, cooling fans, a Peltier cooler or integrated coolant channels circulating coolant, or the like or combinations thereof and claimed subject matter is not limited in this regard.

In an example, delivery vessel 502 may be proximate and/or thermally coupled to one or more heating devices 576 disposed on an exterior of housing 578. Such heating devices serve to control or adjust the temperature of chemical 514 during refilling operations, material processing operations and storage of chemical 514. Heating device 576 may comprise any of a variety of heating devices known to those of skill in the art such as heaters, heating jackets, heating blocks, and/or radial heaters, or the like or combinations thereof and claimed subject matter is not limited in this regard.

In an example, during a refill operation, restrictor 511 may be opened allowing inert gas and chemical 514 to expand into delivery vessel which would cause a pressure drop in delivery vessel 502. Such a decrease in pressure may cause chemical 514 vapor molecules to slow down and cool to facilitate trapping of vapor molecules inside delivery vessel 502. Moreover, the temperature of inner volume 580 may be cooled by cooling device 586 to a lower temperature than incoming chemical 514 additionally promoting solidification of chemical 514 upon entry to delivery vessel 502. During refill, chemical 514 will form a solid. Delivery vessel 502 may maintain a temperature in bottom portion 592 of delivery vessel 502 sufficient to maintain chemical 514 in solid phase prior to material processing operations.

In an example, during a material processing operation, heating device 576 may be configured to heat chemical 514 to a temperature sufficient to change the phase of chemical 514, such as to vaporize and/or sublimate chemical 514. Once vaporized or sublimed, chemical 514 may be transported via chemical delivery line 528 to accumulator 501 and onto reaction chambers 522 and/or 524 for substrate processing.

During material processing, delivery vessel 502 may be configured to operate at a selected temperature based on a desired subliming rate of chemical 514 precursor/reactants. In some examples, the operating temperature is in the range of about 10° C. to about 500° C. Other temperature ranges are possible and claimed subject matter is not limited in this regard. Once depleted of chemical 514, delivery vessel 502 may be refilled from remote refill vessel 504. It may not be necessary to completely deplete delivery vessel 502 of chemical 514 prior to refilling from remote refill vessel 504.

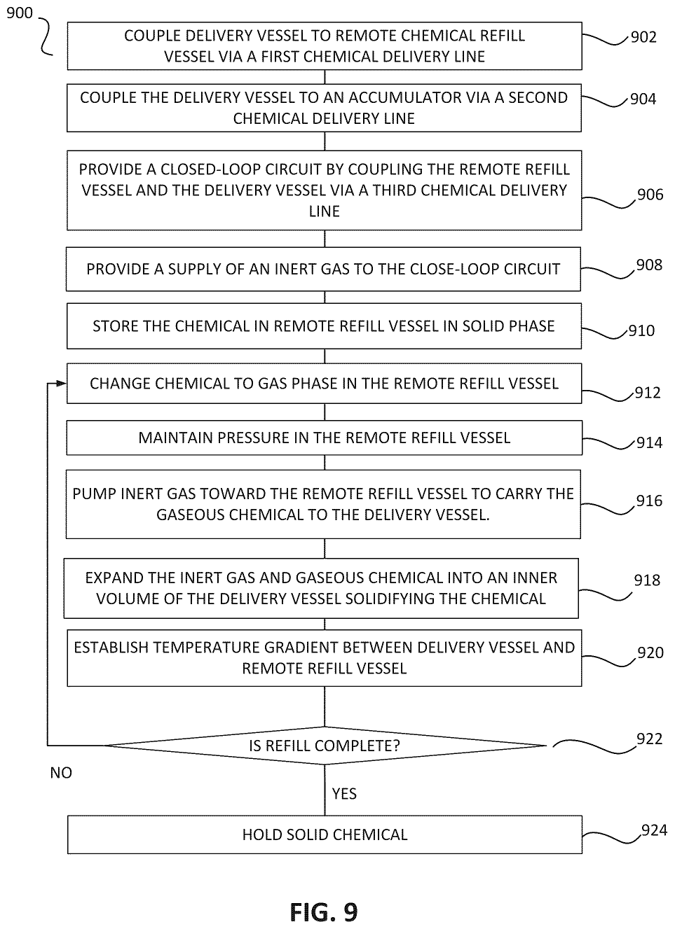

In the illustrated example controller 556 includes a device interface 562, a processor 564, a user interface 566, and a memory 568. The device interface 562 connects the processor 564 to the wired or wireless link 570. The processor 564 may be operably connected to the user interface 566 (e.g., to receive user input and/or provide user output therethrough) and may be disposed in communication with the memory 568. The memory 568 includes a non-transitory machine-readable medium having a plurality of program modules 572 recorded thereon containing instructions that, when read by the processor 564, cause the processor 564 to execute certain operations. Among the operations are operations of a material layer deposition method and methods for refilling a delivery vessel 502 (shown in FIG. 7, FIG. 9 and FIG. 10), as will be described. As will be appreciated by those of skill in the art in view of the present disclosure, the controller 556 may have a different arrangement in other examples and remain within the scope of the present disclosure.

Returning to FIG. 6, in an example, one or more back-up remote refill vessels 690 may be co-located with remote refill vessel 504 to reduce downtime required to replace remote refill vessel 504 when depleted. When remote refill vessel 504 needs to be replaced, back-up remote refill vessels 690 may be quickly coupled to delivery vessel 502 via chemical delivery lines 506 and 530 to avoid downtime waiting for remote refill vessel 504 to be removed and replaced. Alternatively, back-up remote refill vessels 690 may be coupled to remote refill vessel 504 at other opportune idle times, such as between refill operations or upstream events requiring downtime on the substrate processing platform 510.

In an example, the refilling process may be controlled manually and/or refill operations may be partially or fully automated using a variety of sensors for automated feedback control by a controller 556 (see FIG. 5). For example, sensor 610 may be disposed adjacent to or within an inner volume 580 of delivery vessel 502, sensor 612 may be disposed within or adjacent to chemical delivery line 506, sensor 614 may be disposed within or adjacent to chemical delivery line 530, sensor 626 may be disposed adjacent to or within an interior portion 628 of pump 509 and sensor 630 may be disposed adjacent to or within an inner volume 512 of remote refill vessel 504. Sensors 610, 612, 614, 626 and/or 630 may monitor a variety of physical phenomenon such as, for example, acoustics, vibration, chemicals, moisture, flow, light, pressure, force, density, temperature and/or presence, or the like or any combinations thereof. Sensors 610, 612, 614, 626 and/or 630 may, for example, monitor a temperature gradient between remote refill vessel 504 and delivery vessel 502 and/or monitor a temperature of the chemical 514 disposed in at least one of the chemical delivery line 506, chemical delivery line 530, pump 509, delivery vessel 502 or the remote refill vessel 504, or a combination thereof. Sensors 610, 612, 614, 626 and/or 630 may alternatively or additionally monitor a temperature and/or pressure of or within chemical delivery line 506, chemical delivery line 530, pump 509, delivery vessel 502 and/or remote refill vessel 504, or a combination thereof. Sensors 610, 612, 614, 626 and/or 630 may generate sensor data based on the monitoring and send the sensor data to controller 556 (see, FIG. 5) to adjust the various devices to change a monitored parameter (e.g., temperature, pressure, and/or pump cycle time). For example, controller 556 may adjust one or more of delivery vessel 502, remote refill vessel 502, heating devices 574, 576, 634, cooling devices 586 and 588, one or more valves (e.g., valve 516, valve 518, valve 526, valve 618, valve 624), restrictor 511, or pump 509 or a combination thereof based on the sensor data.

In some examples, the electronics and/or computer elements for use in controlling one or more of delivery vessel 502, remote refill vessel 502, heating devices 574, 576, 634, cooling devices 586 and 588, one or more valves (e.g., valve 516, valve 518, valve 526, valve 618, valve 624), restrictor 511, or pump 509 may be found elsewhere in the system. For example, central controllers may control both apparatus of the one or more chambers themselves as well as control the valves that connect to the various vessels and any associated heating or cooling devices. Additionally, one or more valves may be used to control the flow of gas throughout substrate processing system 500.

FIG. 7 is a flow chart that depicts an embodiment of a solid source refill process 700, generally. Process 700 will be described with reference to FIGS. 1-2. Process 700 may begin at block 702, where a delivery vessel (e.g., delivery vessel 102, 302 or 502) may be coupled to a remote refill vessel (e.g., remote refill vessel 104, 304 or 504). The delivery vessel may be disposed at a first location on a substrate processing platform (e.g., substrate processing platform 110, 310 or 510) and the remote refill vessel may be disposed in a second location remote from the substrate processing platform. In an example, the first location may be separated from the second location by a distance of about 1 ft. to about 20 ft., 20 ft. to about 100 ft., 100 ft. to about 200 ft., or 200 ft. to about 500 ft. Other distances are possible and claimed subject matter is not limited in this regard.

The delivery vessel may be coupled to remote refill vessel via chemical delivery line (e.g., chemical delivery line 106, 306, 506 and/or 530). Process 700 may move to block 704, where a chemical (e.g., chemical 114, 314, or 514) may be stored in remote refill vessel in a first phase. In an example, first phase may be solid phase. In another example, the first phase may be liquid or gas. At block 706, the phase of the chemical may be changed to a second phase by action of one or more components (e.g., heating devices 176, 194, 374 or 574, cooling devices 174, 388, or 588, or valves 116, 316, 516, and/or 634) of the remote refill vessel. Such action may comprise heating and/or pressurizing the chemical or chemicals. In an example, the first phase and the second phase are different. Process 700 may move to block 708 where the chemical may be transported to the delivery vessel in the second phase to refill delivery vessel with the chemical(s). The chemical(s) may be transported from the remote refill vessel to delivery vessel by opening of one or more valves (e.g., valves 116, 118, 316, 318, 516, and/or 518) on the chemical delivery line wherein open chemical delivery line puts the remote refill vessel in fluid communication with the delivery vessel. After refill is complete chemical(s) may be transported from the delivery vessel to an accumulator (e.g., accumulator 101, 301, 501) to a reaction chamber (e.g., 138, 140, 338, 340, 538, and/or 540) in fluid communication with the delivery vessel to process a substrate (e.g., 146, 148, 346, 348, 546, and/or 548).

FIG. 8 is a flow chart that depicts an example solid source refill process 800. Process 800 will be described with reference to FIGS. 3-4. Process 800 may begin at block 802, where delivery vessel 302 (see FIG. 4) may be coupled to a remote refill vessel 304 via a chemical delivery line 306. Delivery vessel 302 may be disposed at a first location on a substrate processing platform 310 and remote refill vessel 304 may be disposed in a second location remote from the substrate processing platform 310. Process 800 may continue at block 804, where a solid chemical 314 (e.g., precursor) may be stored in remote refill vessel in a first phase, as a solid.

At block 806, chemical 314 may be converted to a second phase in remote refill vessel 304. For example, chemical 314 may be sublimated or vaporized to form a gaseous form of chemical 314 by exposing chemical 314 to heat and/or pressure to convert the solid to a second phase, a gas. In an example, the heat and/or pressure may be above a boiling or sublimation point of chemical 314.

At block 808, gaseous chemical 314 may be transported to delivery vessel 302 via heated chemical delivery line 306 to maintain the temperature of the chemical 314 above a phase change temperature wherein the phase change temperature is a boiling or sublimation point of the chemical 314. At block 810, pump 309 may operate to pump chemical 314 through chemical delivery line 306 to assist in transport of chemical 314 to delivery vessel 302 in gas phase. At block 812, a temperature gradient between an inner volume 380 of delivery vessel 302 and inner volume 312 of remote refill vessel 304 may be established. A temperature within inner volume 312 may be greater than a temperature of inner volume 380. In an example, maintaining the temperature gradient may comprise actively cooling the delivery vessel 302 with a cooling device such as a plurality of cooling projections 311 disposed within the first inner volume 184. Such active cooling within delivery vessel 302 may lower a temperature within inner volume 380 below a solidification or phase change point and may facilitate returning chemical 314 to the first phase (e.g., a solid) after entering inner volume 380 of delivery vessel 302. At block 814, process 800 may continuously return to block 806 until delivery vessel 302 is refilled. Blocks 806-812 may be performed simultaneously during refilling process. Process 800 moves to block 814 upon completion of the refilling of delivery vessel 304 with chemical 314. At block 816, chemical 314 may be solidified in delivery vessel 302. Chemical 314 may be held in delivery vessel 302 until use in a material processing operation.

FIG. 9 is a flow chart that depicts an example solid source refill process 900. Process 900 will be described with reference to FIGS. 5-6. Process 900 may begin at block 902, where delivery vessel 502 (see FIG. 6) may be coupled to a remote refill vessel 504 via a first chemical delivery line 506. Delivery vessel 502 may be disposed at a first location on a substrate processing platform 510 and remote refill vessel 504 may be disposed in a second location remote from the substrate processing platform 510. At block 904, delivery vessel 502 may be coupled to accumulator 501 via a second chemical delivery line 505. At block 906, remote refill vessel 504 may be coupled to delivery vessel 502 via a third chemical delivery line 530 to provide a closed-loop circuit 503 with the first chemical delivery line 506 between delivery vessel 502 and remote refill vessel 504.

In an example, process 900 may move to block 908 where a supply of an inert gas 616 may be provided to the closed-loop circuit 503. The inert gas 616 may enter the system from accumulator 501 or via an inert gas source 620 coupled to third chemical delivery line 530 via a fourth chemical delivery line 622. One or more gas valves 618 and/or 624 may control the flow of inert gas 616 to prime the closed-loop circuit 503.

Process 900 may continue at block 910, where chemical 514 (e.g., precursor) may be stored in remote refill vessel in a first phase, as a solid. At block 912, chemical 514 may be converted to a second phase in remote refill vessel 504. For example, chemical 514 may be sublimated or vaporized to form a gaseous form of chemical 514 by exposing chemical 514 to heat and/or pressure to convert the solid to a second phase, a gas. In an example, the heat and/or pressure may be above a boiling or sublimation point of chemical 514.

At block 914, pressure may be maintained in the remote refill vessel 504 between a compressor pump 509 coupled to the third chemical delivery line 530 and a restrictor 511 coupled to the first chemical delivery line 506 upstream of the delivery vessel 502. At block 916, inert gas 616 may be pumped via compressor pump 509 toward the remote refill vessel 504 to carry chemical 514 in gas phase to the delivery vessel 502. At block 918, the inert gas 616 and chemical 514 in the second phase may expand into an inner volume 580 of delivery vessel 502. Upon expansion into delivery vessel 502, the mixture of inert gas 616 and gaseous chemical 514 may cause pressure within inner volume 580 to drop. The decrease in pressure would cause vapor molecules to slow and cool down helping trap chemical 514 molecules inside delivery vessel 502. Such expansion and cooling may solidify chemical 514 within delivery vessel 502 responsive to the resulting pressure drop within delivery vessel 502.

At block 920, a temperature gradient between an inner volume 580 of delivery vessel 502 and inner volume 512 of remote refill vessel 504 may be established. A temperature within inner volume 512 may be greater than a temperature of inner volume 580. In an example, maintaining the temperature gradient may comprise actively cooling the delivery vessel 502 with a cooling device 586. Such active cooling within delivery vessel 502 may lower a temperature within inner volume 580 below a solidification or phase change point of chemical 514 and may facilitate returning chemical 514 to solid phase within inner volume 580 of delivery vessel 502.

At block 922, process 800 may continuously return to block 912 until delivery vessel 302 is refilled. Blocks 912-922 may be performed simultaneously during refilling process. Process 900 moves to block 924 upon completion of the refilling of delivery vessel 504 with chemical 514. At block 924, chemical 514 may be solidified in delivery vessel 502. Chemical 514 may be held in delivery vessel 502 until use in a material processing operation such as described with respect to FIG. 10. At the end of the transfer, trapped inert in recipient vessel 504 may be burped out prior to any process recovery.

FIG. 10 is a flow chart depicting a substrate processing process 1000 which may proceed subsequent to solid source refill process 800 (see FIG. 8) and/or process 900 (see FIG. 9). Process 1000 begins at block 1002 where chemical (e.g., chemical 314 and/or chemical 514) may be sublimated within a delivery vessel (e.g., delivery vessel 302 and/or delivery vessel 502).

In an example, at block 1004, the sublimated chemical (e.g., chemical 314 and/or chemical 514) may be transported from the delivery vessel (e.g., 302 and/or 502) to the accumulator (e.g., accumulator 301 and/or accumulator 501) via the second chemical delivery line (e.g., second chemical delivery line 305 and/or second chemical delivery line 505). At block 1006, the second chemical delivery line (e.g., second chemical delivery line 305 and/or second chemical delivery line 505) may be heated to a temperature sufficient to maintain the chemical (e.g., chemical 314 and/or chemical 514) in a gaseous state. At block 1008, the accumulator (e.g., accumulator 301 and/or accumulator 501) may be coupled to one or more reaction chambers (e.g., reaction chamber 338, reaction chambers 340, reaction chamber 538 and/or reaction chamber 540). At block 1010, the chemical (e.g., chemical 314 and/or chemical 514) may be transported from the accumulator (e.g., accumulator 301 and/or accumulator 501) to one or more reaction chambers (e.g., reaction chamber 338, reaction chamber 340, reaction chamber 538 and/or reaction chambers 540) to carry out processing operations on respective substrates (e.g., substrate 346, substrate 348, substrate 546, and/or substrate 548) using the chemical (e.g., chemical 314 and/or chemical 514).

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The headings provided herein, if any, are for convenience only and do not necessarily affect the scope or meaning of the devices and methods disclosed herein.

1. A method, comprising:
coupling a delivery vessel disposed at a first location on a substrate processing platform to a remote refill vessel disposed in a second location remote from the substrate processing platform via a first chemical delivery line;
storing a chemical in the remote refill vessel in a first phase;
changing the chemical in the remote refill vessel to a second phase;
transporting the chemical in the second phase, to the delivery vessel via the first chemical delivery line;
heating the first chemical delivery line to a first temperature equal to or above a phase change temperature of the chemical; and
coupling the delivery vessel to an accumulator via a second chemical delivery line.

2. The method of claim 1, wherein the first phase is solid and the second phase is liquid and wherein the changing the phase of the chemical further comprises melting the chemical by applying heat to the chemical or applying pressure to the chemical, or a combination thereof.

3. The method of claim 1, wherein the first phase is solid and the second phase is gas and wherein the changing the phase of the chemical further comprises sublimating the chemical by applying heat to the chemical or reducing a pressure applied to the chemical, or a combination thereof.

4. The method of claim 1, further comprising disposing the remote refill vessel in a sub-fab.

5. The method of claim 1, wherein transporting the chemical in the second phase further comprises:
coupling the remote refill vessel and the delivery vessel via a third chemical delivery line to provide a closed-loop circuit with the first chemical delivery line between the delivery vessel and the remote refill vessel;
providing a supply of an inert gas via an inert gas supply vessel coupled to the third chemical delivery line via a gas valve to prime the closed-loop circuit with the inert gas; and
closing the gas valve subsequent to the priming.

6. The method of claim 5, further comprising, maintaining pressure in the remote refill vessel between a compressor pump coupled to the third chemical delivery line and a restrictor coupled to the first chemical delivery line, upstream of the delivery vessel.

7. The method of claim 6, further comprising, pumping, with the compressor pump, the inert gas toward the remote refill vessel to carry the chemical in the second phase to the delivery vessel.

8. The method of claim 7, further comprising, expanding the inert gas and chemical in the second phase into an inner volume of the delivery vessel and solidifying the chemical in the delivery vessel, responsive to a resulting pressure drop within the delivery vessel.

9. The method of claim 1, further comprising:
sublimating the chemical within the delivery vessel;
transporting the sublimated chemical from the delivery vessel to the accumulator via the second chemical delivery line;
heating the second chemical delivery line to a second temperature sufficient to maintain the chemical in a gaseous state;
coupling the accumulator to a reaction chamber; and
transporting the chemical from the accumulator to the reaction chamber.

10. The method of claim 1, further comprising:
maintaining a temperature gradient between a first inner volume of the delivery vessel and a second inner volume of the remote refill vessel; and
returning the chemical to the first phase within the first inner volume.

11. The method of claim 10, wherein maintaining the temperature gradient further comprises actively cooling the delivery vessel via a plurality of cooling projections disposed within the first inner volume.

12. The method of claim 1, wherein transporting the chemical in the second phase further comprises pumping the chemical through the first chemical delivery line via a pump coupled to the first chemical delivery line.

13. A substrate processing system, comprising:
a delivery vessel having a first inner volume, disposed in a first location on a substrate processing platform;
a remote refill vessel in fluid communication with the delivery vessel via a first chemical delivery line, the remote refill vessel comprising a second inner volume greater than the first inner volume and disposed in a second location remote from the substrate processing platform;
an accumulator coupled between the delivery vessel and a reaction chamber via a second chemical delivery line; and
a first heating device proximate the remote refill vessel, operable to heat a chemical disposed in the remote refill vessel sufficient to change the chemical from a first phase to a second phase.

14. The substrate processing system of claim 13, wherein the first chemical delivery line is coupled to a second heating device operable to maintain the first chemical delivery line at a transport temperature higher than a phase change temperature of the chemical.

15. The substrate processing system of claim 13, wherein the first chemical delivery line is coupled to a mechanical pump configured to direct the chemical in the second phase through the first chemical delivery line from the remote refill vessel to the delivery vessel.

16. The substrate processing system of claim 14, wherein the delivery vessel is coupled to a third heating device, or a cooling device, or a combination thereof, wherein the first chemical delivery line is coupled to the delivery vessel via an inlet valve.

17. The substrate processing system of claim 16, wherein the cooling device comprises a plurality of cooling projections disposed at a bottom portion of the delivery vessel wherein a temperature of the cooling projections is selected to return the chemical to the first phase from the second phase.

18. The substrate processing system of claim 16, further comprising:
at least one sensor disposed in or adjacent to the first chemical delivery line, the second chemical delivery line, a pump, the delivery vessel or the remote refill vessel, or a combination thereof, to monitor temperature, pressure or pump cycle time or a combination thereof of the chemical and to generate sensor data based on the monitoring; and
at least one controller communicatively coupled to the at least one sensor and communicatively coupled to the first heating device, the second heating device, the third heating device, the cooling device or the pump, or a combination thereof, the at least one controller configured to receive the sensor data and adjust the first heating device, the second heating device, the third heating device, the pump or the cooling device, or a combination thereof, based on the sensor data.

19. The substrate processing system of claim 16, wherein the first phase of the chemical is solid and the second phase of the chemical is gaseous, further comprising:
a third chemical delivery line coupled between the remote refill vessel and the delivery vessel;
a compressor pump coupled to the third chemical delivery line upstream of an inert gas source coupled to the third chemical delivery line, wherein the compressor pump is operable to at least direct the inert gas from the inert gas source to the remote refill vessel; and
a restrictor coupled to the first chemical delivery line upstream of the delivery vessel to maintain the inert gas and the gaseous chemical at a first pressure, between the compressor pump and the restrictor, that is higher than a second pressure within the delivery vessel, and wherein the restrictor is operable to open to expand the inert gas and the gaseous chemical into the delivery vessel to solidify the chemical within the delivery vessel.

20. The substrate processing system of claim 19, further comprising:
at least one sensor disposed in or adjacent to the first chemical delivery line, the third chemical delivery line, the compressor pump, the restrictor, the inert gas source, the delivery vessel, or the remote refill vessel, or a combination thereof, to monitor a temperature or a pressure or combination thereof of the chemical and to generate sensor data based on the monitoring; and
at least one controller communicatively coupled to the at least one sensor and communicatively coupled to the first heating device, the second heating device, the third heating device, the compressor pump, the restrictor, or one or more valves coupled to any of the delivery vessel, the remote refill vessel or the inert gas source, or a combination thereof,
wherein the at least one controller is configured to receive the sensor data and adjust the first heating device, the second heating device, the third heating device, the compressor pump, the restrictor, or the one or more valves coupled to any of the delivery vessel, the remote refill vessel or the inert gas source, or a combination thereof, based on the sensor data.

21. The substrate processing system of claim 13, wherein the first phase is solid and the second phase is gas or liquid, or a combination thereof.
